(19) United States
(12) Patent Application Publication
(10) Pub. No.: US 2025/0006515 A1
(43) Pub. Date: Jan. 2, 2025

(54) SHOWERHEAD WITH HOLE SIZES FOR RADICAL SPECIES DELIVERY

(71) Applicant: Lam Research Corporation, Fremont, CA (US)

(72) Inventors: Aaron Blake MILLER, West Linn, OR (US); Gopinath BHIMARASETTI, Portland, OR (US); Kyle Watt HART, Beaverton, OR (US)

(21) Appl. No.: 18/703,982

(22) PCT Filed: Oct. 27, 2022
(86) PCT No.: PCT/US2022/078786

§ 371 Date: Apr. 23, 2024

Related U.S. Application Data
(60) Provisional application No. 63/263,290, filed on Oct. 29, 2021.

(51) Int. Cl. H01L 21/67; B05B 1/14; H01J 37/32

(52) U.S. Cl. CPC H01L 21/67017; B05B 1/14; H01J 37/3244

(57) ABSTRACT

A showerhead comprises a first set of holes and a second set of holes. The first set of holes have a greater diameter and length than the second set of holes. The first set of holes extend through a thickness of the showerhead. In some embodiments, the showerhead includes a base portion and a cylindrical portion extending perpendicularly from the base portion. The base portion may define a plenum that is in fluid communication with the second set of holes but separate from the first set of holes. The second set of holes extend from the plenum to a bottom surface of the showerhead. In some implementations, the first diameter of the first set of holes may be optimized to filter ions from a plasma, pass radicals from the plasma through the showerhead, and to limit back-diffusion of precursors through the showerhead.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### FIELD

Implementations herein relate to semiconductor substrate processing systems and, more particularly to showerheads used in plasma processing systems.

### BACKGROUND

Semiconductor substrate processing apparatuses are used to process semiconductor substrates by techniques including etching, physical vapor deposition (PVD), chemical vapor deposition (CVD), plasma-enhanced chemical vapor deposition (PECVD), atomic layer deposition (ALD), plasma-enhanced atomic layer deposition (PEALD), pulsed deposition layer (PDL), plasma-enhanced pulsed deposition layer (PEPDL), and resist removal. One type of semiconductor substrate processing apparatus is a plasma processing apparatus. Many semiconductor processes expose a wafer to plasma and expose the wafer to temperatures above ambient or room temperature. Plasma may be struck in the semiconductor substrate processing apparatus in a processing chamber. Alternatively, plasma may be generated remotely from (i.e., outside) the processing chamber. Plasma generated outside the processing chamber is called remote plasma and may be generated using any method including capacitively coupled plasma (CCP), inductively coupled plasma (ICP), transformer coupled plasma (TCP), and microwave (MW) plasma.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Provided herein is a showerhead for use in a semiconductor processing apparatus. The showerhead includes a base portion having a plenum within the showerhead, and a cylindrical portion extending perpendicularly from the base portion, the base portion having a greater diameter than an outer diameter of the cylindrical portion, where the base portion comprises a first set of holes each having a first diameter and a first length and a second set of holes each having a second diameter and a second length. The first set of holes and the second set of holes are distributed from a center of the base portion to an inner diameter of the cylindrical portion, where the first set of holes extend from a top surface of the base portion to a bottom surface of the base portion, where the second set of holes extend from the plenum to the bottom surface of the base portion, where the first diameter is greater than the second diameter and the first length is greater than the second length, and where a ratio of a sum of a cross-sectional area of the first set of holes to a cross-sectional area of the cylindrical portion is between about 0.5% and about 3.0%.

In some implementations, the first and second sets of holes are arranged in a hexagonal pattern, a triangular pattern, or a combination of a hexagonal pattern and a triangular pattern. In some implementations, a density of the first and second sets of holes is between about 3 holes per square inch and about 6 holes per square inch. In some implementations, a ratio of the first length (L₁) to the first diameter (D₁) is between about 8 and about 15. In some implementations, the ratio of the first length (L₁) to the first diameter (D₁) is between about 10 and 12. In some implementations, the first diameter is between about 0.03 inches and about 0.1 inches. In some implementations, the showerhead further includes a first component having the base portion and the cylindrical portion, a second component being disc-shaped and including first through-holes aligned with the first set of holes in the base portion, where the second component has a top surface, side surfaces, and a bottom surface attached to the base portion of the first component on a side opposite to the cylindrical portion and defining the plenum that is in fluid communication with the second set of holes and separate from the first set of holes, and a third component being disc-shaped and including second through-holes aligned with the first through-holes in the second component and with the first set of holes in the first component, and having a bottom surface attached to the top surface of the second component. In some implementations, the top surface of the second component includes a pair of arc-shaped grooves along a periphery and on opposite ends of the top surface and where the top surface of the second component further includes a plurality of grooves extending between the pair of arc-shaped grooves. In some implementations, the third component includes a gas inlet in fluid communication with the plenum, a fluid inlet in fluid communication with the first one of the pair of arc-shaped grooves, and a fluid outlet in fluid communication with the second one of the pair of arc-shaped grooves. In some implementations, the showerhead is configured to limit back-diffusion of gases supplied from the second set of holes through the first set of holes. In some implementations, the inner diameter of the cylindrical portion is greater than a diameter of a substrate being processed. In some implementations, the first set of holes are arranged in a hexagonal pattern, where the second set of holes lie on vertices of triangles within hexagons defined by the first set of holes, and where one of the first set of holes lies within each of the triangles. In some implementations, the second set of holes are arranged in a hexagonal pattern, where the first set of holes lie on vertices of triangles within hexagons defined by the second set of holes, and where one of the second set of holes lies within each of the triangles. In some implementations, a ratio of a number of the first set of holes to a number of the second set of holes is between about 1.00 and about 1.05.

Also provided herein is a showerhead for use in a semiconductor processing apparatus. The showerhead includes a first component comprising a disc-shaped portion and a cylindrical portion extending perpendicularly from the disc-shaped portion, the disc-shaped portion having a greater diameter than an outer diameter of the cylindrical portion, the disc-shaped portion including a first set of holes and a second set of holes, the first set of holes each having a first length and a first diameter and the second set of holes each having a second length and a second diameter, where the first diameter is greater than the second diameter and the first length is greater than the second length, where the first and second sets of holes are distributed from a center of the disc-shaped portion to an inner diameter of the cylindrical portion, where a ratio of a sum of a cross-sectional area of the first set of holes to a cross-sectional area of the cylindrical portion is between about 0.5% and about 3.0%. The showerhead further includes a second component being disc-shaped and comprising first through-holes aligned with the first set of holes in the first component, where the second component has a top surface, side surfaces, and a bottom surface attached to the disc-shaped portion of the first component on a side opposite to the cylindrical portion and defining a plenum that is in fluid communication with the second set of holes in the first component and that is separate from the first set of holes in the first component. The showerhead further includes a third component being disc-shaped and including second through-holes aligned with the first set of holes in the second component and with the first set of holes in the first component, where the third component has a bottom surface attached to the top surface of the second component.

In some implementations, where the top surface of the second component includes a pair of arc-shaped grooves along a periphery and on opposite ends of the top surface of the second component, and where the top surface of the second component further includes a plurality of grooves extending between the pair of arc-shaped grooves. In some implementations, the third component further includes an annular ridge on a top surface of the third component along a periphery of the third component, where the third component further includes a recess extending from an inner diameter of the annular ridge to a center of the top surface of the third component. In some implementations, the first and second sets of holes are arranged in a hexagonal pattern, a triangular pattern, or a combination of a hexagonal pattern and a triangular pattern. In some implementations, a density of the first and second sets of holes is between about 3 holes per square inch and about 6 holes per square inch. In some implementations, a ratio of the first length (L₁) to the first diameter (D₁) is between about 8 and about 15.

Also provided herein is a plasma apparatus including a processing chamber, a pedestal in the processing chamber and configured to support a substrate, a plasma source disposed above the processing chamber, and a showerhead disposed between the processing chamber and the plasma source. The showerhead includes a base portion having a plenum within the showerhead, and a cylindrical portion extending perpendicularly from the base portion, the base portion having a greater diameter than an outer diameter of the cylindrical portion, where the base portion includes a first set of holes each having a first diameter and a first length and a second set of holes each having a second diameter and a second length, where the first set of holes and the second set of holes are distributed from a center of the base portion to an inner diameter of the cylindrical portion, where the first set of holes extend from a top surface of the base portion to a bottom surface of the base portion, where the second set of holes extend from the plenum to the bottom surface of the base portion, where the first diameter is greater than the second diameter and the first length is greater than the second length, where a ratio of a sum of a cross-sectional area of the first set of holes to a cross-sectional area of the cylindrical portion is between about 0.5% and about 3.0%.

In some implementations, the plasma source is configured to generate plasma and supply the plasma to the showerhead, where the first set of holes in the showerhead is configured to filter ions from the plasma and pass radicals from the plasma through the showerhead into the processing chamber. In some implementations, the first and second sets of holes are arranged in a hexagonal pattern, a triangular pattern, or a combination of a hexagonal pattern and a triangular pattern. In some implementations, a density of the first and second sets of holes is between about 3 holes per square inch and about 6 holes per square inch. In some implementations, a ratio of the first length (L₁) to the first diameter (D₁) is between about 8 and about 15.

### BRIEF DESCRIPTION OF THE DRAWINGS

FIG. 1 shows a schematic illustration of an example semiconductor substrate processing system utilizing remote plasma and a showerhead according to some implementations.

FIG. 2 shows a side cross-sectional view of a showerhead configured for use in a semiconductor substrate processing system according to some implementations.

FIG. 3 is a magnified detailed view of the side cross-sectional view of the showerhead of FIG. 2 according to some implementations.

FIG. 4 shows a perspective cross-sectional view of the showerhead of FIG. 2 according to some implementations.

FIG. 5 shows a top view of a cooling channel arranged in the showerhead of FIG. 2 for circulating coolant in the showerhead according to some implementations.

FIG. 6 shows a bottom view of the showerhead of FIG. 2 with a hole pattern used in the showerhead according to some implementations.

FIG. 7 is a magnified detailed view of the bottom view of the showerhead of FIG. 2 with the hole pattern of FIG. 6.

FIG. 8 shows an off-angle bottom view of the showerhead of FIG. 2 according to some implementations.

FIG. 9 shows an isometric top view of the showerhead of FIG. 2 according to some implementations.

In the drawings, reference numbers may be reused to identify similar and/or identical elements.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

The present disclosure relates to substrate processing systems that use a showerhead. The showerhead may have two sets of holes of different dimensions. A first set of holes may be larger in diameter than a second set of holes. In some embodiments, the first set of holes may be at least two times larger in diameter than the second set of holes. In some embodiments, the first set of holes may be longer in length than the second set of holes. The first set of holes may extend through a thickness of the showerhead, and the second set of holes may extend only partially through the thickness of the showerhead. A ratio of the sum of a cross-sectional area of the first set of holes to a cross-sectional area defined by an inner diameter of a cylindrical portion of the showerhead is equal to or less than 3%, equal to or less than 2.5%, equal to or less than 2%, or between 0.5% and 3%. A density of the first set of holes and the second set of holes is between about 3 and 6 holes per square inch, or between about 4 holes and about 5 holes per square inch.

The showerhead of the present disclosure may be used in a semiconductor processing apparatus configured to generate plasma. The showerhead may be configured to filter damage-causing ions from the remote plasma and allow radicals in the remote plasma to pass into a processing chamber. The radicals are delivered through the second set of holes, where the second set of holes provide fluid communication between a remote plasma source and the processing chamber via the showerhead. Holes in the showerhead that connect the remote plasma source to the processing chamber are optimized to filter the ions and pass the radicals from the remote plasma. For convenience, these holes are called “radical holes” throughout the present disclosure.

In addition, one or more precursors are supplied to the processing chamber through a separate plenum in the showerhead. In some embodiments, the separate plenum in the showerhead may be optimized for dose uniformity and purge efficiency in atomic layer deposition (ALD) or chemical vapor deposition (CVD) operations. The precursors are supplied from the separate plenum into the processing chamber through the second set of holes in the showerhead. For convenience, these holes are called “precursor holes” throughout the present disclosure. Separating the delivery of radicals and precursors allows independent optimization of both to achieve optimal film properties and uniformity. It will be understood that the showerhead of the present disclosure may be implemented in plasma processing apparatuses configured for deposition operations and/or etch operations.

Characteristics such as diameter, aspect ratio, and quantity of the radical holes are selected to optimize the amount of radicals that are delivered to a substrate in the processing chamber while also balancing the effectiveness of filtering ions that can otherwise cause damage to the substrate. Characteristics such as a percentage of open area for radicals to pass from a plasma source through the showerhead are selected to optimize an amount of radicals that are delivered to the substrate while limiting the back-streaming of precursors and unwanted species through the showerhead. In some implementations, a pattern (e.g., layout, distribution, and density) of the radical holes and the precursor holes may also be optimized to provide film uniformity across the entire substrate. This showerhead architecture can be used with any type of plasma source and can also be used with remote plasma enhanced ALD processes, CVD processes, or etching processes.

The showerhead includes a planar base portion and a cylindrical portion that extends perpendicularly downward from a periphery of the base portion. The base portion includes cooling and precursor plenums, the radical holes, and the precursor holes. The cylindrical portion has an outer wall and an inner wall. The inner wall of the cylindrical portion defines a bore of the showerhead. A pedestal that supports the substrate is arranged in the processing chamber directly below the base portion of the showerhead. The pedestal includes a planar top portion and a vertical base portion that extends perpendicularly downward from a center of the top portion. An inner diameter (ID) of the cylindrical portion of the showerhead (i.e., the diameter of the inner wall of the showerhead) is greater than an outer diameter (OD) of the top portion of the pedestal. The inner wall of the cylindrical portion of the showerhead surrounds and extends vertically below the top portion of the pedestal. The cylindrical portion of the showerhead shrouds the top portion of the pedestal. The pedestal is moved down to load the substrate, moved up to process the substrate, and moved down to remove the substrate. The top portion of the pedestal can be moved vertically up and down within the cylindrical portion of the showerhead to adjust a gap between the base portion of the showerhead and the top portion of the pedestal.

The cylindrical portion of the showerhead provides a relatively stable thermal and gas flow environment around an edge of the pedestal, which in turn simplifies the process of varying a gap between the showerhead and the pedestal. Specifically, the cylindrical portion of the showerhead, which extends vertically below the top portion of the pedestal, provides a symmetric thermal boundary condition (i.e., a region of relatively constant temperature) around the edge of the pedestal while the pedestal is moved vertically within the cylindrical portion of the showerhead to adjust the gap between the showerhead and the pedestal.

In addition, the cylindrical portion of the showerhead also provides a relatively constant constriction to gas flow around the edge of the pedestal while the pedestal is moved within the cylindrical portion of the showerhead, which simplifies the process of controlling a micro-volume of gases in the gap between the showerhead and the pedestal in deposition (e.g., ALD) processes. A tunable gap between the showerhead and the pedestal allows precise control of the micro-volume in deposition processes. A narrow gap between the showerhead and the pedestal prevents depletion of radicals in the micro-volume in deposition processes. These and other features of the showerhead of the present disclosure are described below in detail.

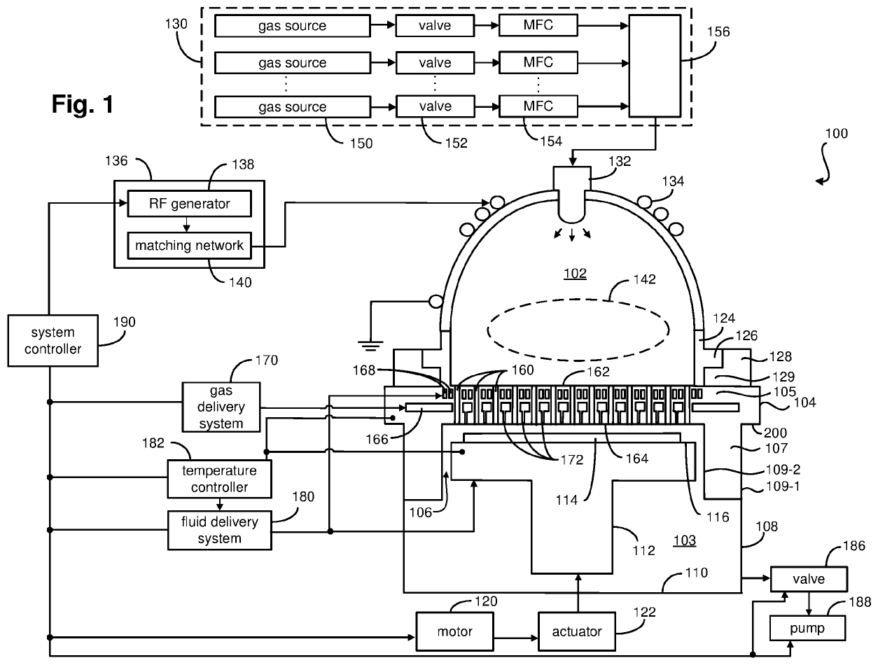

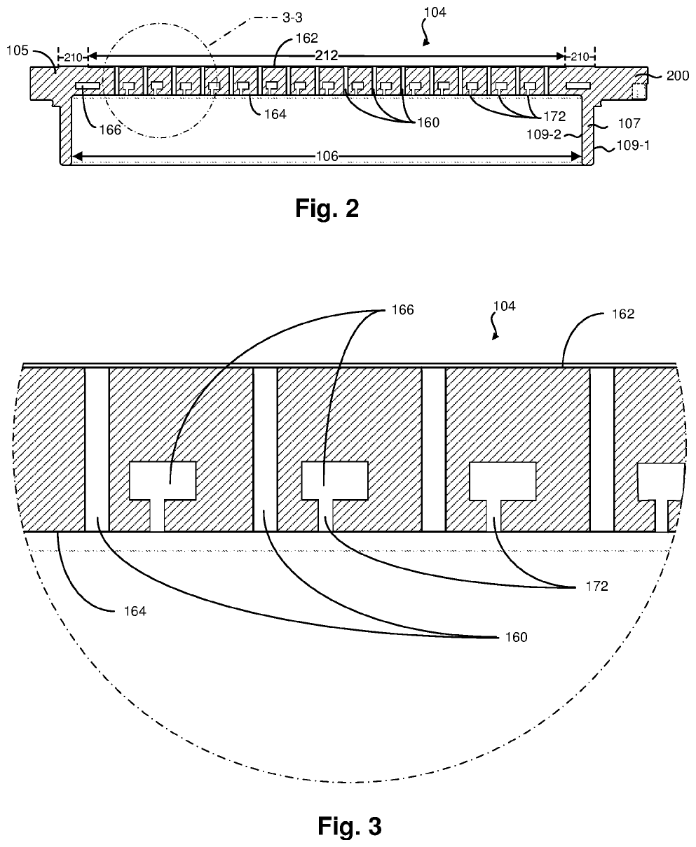

FIG. 1 shows a schematic illustration of an example semiconductor substrate processing system utilizing remote plasma and a showerhead according to some implementations. FIG. 1 shows a substrate processing system 100. The substrate processing system 100 comprises a processing chamber 103 and a showerhead 104. The showerhead 104 can be made of a metal (e.g., aluminum) or an alloy. The showerhead 104 comprises a planar base portion 105 and a cylindrical portion 107 that extends perpendicularly downward from the base portion 105. The base portion 105 extends radially outward at the top of the cylindrical portion 107 forming a flange 200. The base portion 105 is described below in further detail with reference to FIGS. 2-4. The cylindrical portion 107 has an outer wall 109-1 and an inner wall 109-2. The inner wall 109-2 of the cylindrical portion 107 defines a bore 106 of the showerhead 104 (visible in FIG. 2). A diameter of the bore 106 is equal to a diameter of the inner wall 109-2 of the cylindrical portion 107 (i.e., an inner diameter of the cylindrical portion 107) of the showerhead 104.

The processing chamber 103 has a sidewall 108 and a bottom wall 110. The sidewall 108 is attached to the bottom of the cylindrical portion 107 of the showerhead 104. The sidewall 108 is perpendicular to the base portion 105 of the showerhead 104 and extends vertically downward from the bottom of the outer wall 109-1 of the cylindrical portion 107 of the showerhead 104. The bottom wall 110 of the processing chamber 103 is parallel to the base portion 105 of the showerhead 104 and perpendicular to the sidewall 108 of the processing chamber 103 and is attached to the sidewall 108 of the processing chamber 103.

The substrate processing system 100 comprises a plasma source 102 arranged above the showerhead 104. The showerhead 104 is arranged between the plasma source 102 and the processing chamber 103. The showerhead 104 separates the plasma source 102 from the processing chamber 103. The plasma source 102 is described below in further detail.

A pedestal 112 is arranged in the processing chamber 103 directly below the showerhead 104. A substrate 114 is arranged on a top surface 116 of the pedestal 112 during processing. The top surface 116 of the pedestal 112 can be planar and parallel to the base portion 105 of the showerhead 104 and parallel to the bottom wall 110 of the processing chamber 103. Accordingly, the substrate 114 is parallel to the top surface 116 of the pedestal 112, the base portion 105 of the showerhead 104, and the bottom wall 110 of the processing chamber 103. The inner diameter of the cylindrical portion 107 of the showerhead 104 (i.e., the diameter of the inner wall 109-2 of the showerhead 104) is greater than an outer diameter of the top surface 116 of the pedestal 112. The inner diameter of the cylindrical portion 107 of the showerhead 104 (i.e., the diameter of the inner wall 109-2 of the showerhead 104) is also greater than an outer diameter of the substrate 114.

An actuator 120 driven by a motor 122 can move the pedestal 112 vertically up and down relative to the showerhead 104 within the cylindrical portion 107 of the showerhead 104. The plasma source 102 and the showerhead 104 may be fixed relative to the pedestal 112. A gap between a bottom of the base portion 105 of the showerhead 104 and the top surface 116 of the pedestal 112 may be adjusted by vertically moving the pedestal 112 within the cylindrical portion 107 of the showerhead 104. For example, the gap between the bottom of the base portion 105 of the showerhead 104 and the top surface 116 of the pedestal 112 may be equal to or less than about 0.2 inches, equal to or less than about 0.15 inches, or equal to or less than about 0.11 inches.

The plasma source 102 may be dome-shaped as shown or may be of any other shape. A bottom end of the plasma source 102 is open and is attached to a top end of a first cylindrical component 124. The first cylindrical component 124 has a first flange 126 that extends radially outwardly from about a center of the first cylindrical component 124. Accordingly, the first cylindrical component 124 has a shape of the letter “T” with the letter “T” rotated left by 90 degrees.

A second cylindrical component 128 surrounds the first cylindrical component 124. The second cylindrical component 128 has a second flange 129 that extends radially inwardly from a bottom end of the second cylindrical component 128. Accordingly, the second cylindrical component 128 has a shape of the letter “L” with the letter “L” flipped horizontally. The first flange 126 of the first cylindrical component 124 overhangs the second flange 129 of the second cylindrical component 128. The bottom ends of the first and second cylindrical components 124, 128 are attached to the top of the base portion 105 of showerhead 104 near the periphery of the base portion 105 of the showerhead 104.

By way of an illustration, the plasma source 102 generates a remote plasma (i.e., plasma outside the processing chamber 103) using ICP. However, it will be understood that the plasma source 102 may generate remote plasma using other methods such as CCP, TCP, or MW. The plasma source 102 receives one or more gases received from a gas distribution system 130 via a gas injector 132 arranged at the top of the plasma source 102 although gases may be injected into the plasma source 102 in other ways. A coil 134 may be arranged around the plasma source 102. A first end of the coil 134 is grounded, and a second end of the coil 134 is connected to an RF generating system 136.

The RF generating system 136 generates and outputs RF power to the coil 134. By way of an example, the RF generating system 136 may include an RF generator 138 that generates RF power. The RF power is delivered by a matching network 140 to the coil 134. The RF power supplied to the coil 134 ignites the gas or gases injected by the gas injector 132 into the plasma source 102 and generates a plasma 142. Since the plasma source 102 generates the plasma 142 remotely from (i.e., outside) the processing chamber 103, the plasma 142 is called a remote plasma 142.

The gas distribution system 130 includes one or more gas sources 150. The one or more gas sources 150 are connected by valves 152 and mass flow controllers 154 to a manifold 156. The manifold 156 is connected to the gas injector for delivery of the one or more gases to the plasma source 102.

The showerhead 104 is described below in further detail with reference to FIGS. 2-9. Briefly, the base portion 105 of the showerhead 104 comprises a first set of holes 160. The first set of holes 160 may also be referred to as radical holes 160. The first set of holes 160 extend from a top surface 162 of the base portion 105 of the showerhead 104 to a substrate-facing bottom surface 164 of the base portion 105 of the showerhead 104 (also called a faceplate 164). In other words, the first set of holes 160 extend completely through a thickness of the showerhead 104.

In addition, the base portion 105 of the showerhead 104 comprises a plenum 166 that is separate from and not in fluid communication with the first set of holes 160. The plenum 166 receives one or more precursor gases from a gas delivery system 170. The base portion 105 of the showerhead 104 further comprises a second set of holes 172. The second set of holes 172 may also be referred to as precursor holes 172. The second set of holes 172 extend from the plenum 166 to the faceplate 164 of the showerhead 104. The first set of holes 160 are not in fluid communication with the plenum 166 and the second set of holes 172. The first set of holes 160 are greater in diameter and length than the second set of holes 172. In some embodiments, the first set of holes 160 may have a diameter that is at least two times greater than the second set of holes 172.

The base portion 105 of the showerhead 104 may further comprise a plurality of grooves 168. The grooves 168 form a cooling channel through which a coolant flows. A fluid delivery system 180 supplies the coolant to the grooves 168 through an inlet in the base portion 105 of the showerhead 104.

One or more temperature sensors (not shown) may be disposed in the base portion 105 of the showerhead 104. The one or more temperature sensors may be connected to a temperature controller 182. The temperature controller 182 may control the supply of the coolant from the fluid delivery system 180 to the grooves 168 to control a temperature of the showerhead 104.

Further, while not shown, the pedestal 112 may include one or more heaters, a cooling system that receives a coolant from the fluid delivery system 180, and the one or more temperature sensors. The temperature controller 182 may be connected to the one or more temperature sensors in the pedestal 112. The temperature controller 182 may control power supply to the one or more heaters. The temperature controller 182 may control the supply of the coolant from the fluid delivery system 180 to the cooling system in the pedestal 112 to control the temperature of the pedestal 112.

A valve 186 and pump 188 may control pressure in the processing chamber 103 and to evacuate reactants from the processing chamber 103 during processing. A system controller 190 may control the components of the substrate processing system 100 described above.

As described above, the showerhead 104 filters ions from the remote plasma 142 and passes radicals from the remote plasma 142 through the radical holes 160 into the processing chamber 103. In some embodiments, the remote plasma 142 may be used for etch, treatment, cleaning, or deposition operations associated with processing the substrate 114. For instance, the radicals may react with the precursors in the gap between the showerhead 104 and the pedestal 112, and a thin film may be deposited on the substrate 114 using a deposition process such as ALD or CVD. The open area provided by the radical holes 160 for the radicals to pass through the showerhead 104, the density and pattern of the radical holes 160 and the precursor holes 172, and the structural and functional properties of the cylindrical portion 107 of the showerhead 104, all of which are described below in detail, may provide near-zero radial and azimuthal non-uniformity in films deposited using the showerhead 104.

FIG. 2 shows a side cross-sectional view of a showerhead configured for use in a semiconductor substrate processing system according to some implementations. FIG. 3 is a magnified detailed view of the side cross-sectional view of the showerhead of FIG. 2 according to some implementations. The showerhead 104 includes the base portion 105 and the cylindrical portion 107 that extends vertically downwards from the base portion 105 of the showerhead 104. The base portion 105 of the showerhead 104 is horizontal and is parallel to the top surface 116 of the pedestal 112 (see FIG. 1) and to the bottom wall 110 of the processing chamber 103 (see FIG. 1). The base portion 105 extends radially outwardly from an outer diameter of the cylindrical portion 107 to form a flange 200. The flange 200 may be fastened to a top plate (not shown) of the processing chamber 103 using a fastener (not shown). An O-ring (not shown) may be disposed between the flange 200 and the top plate to form a seal between the showerhead 104 and the top plate.

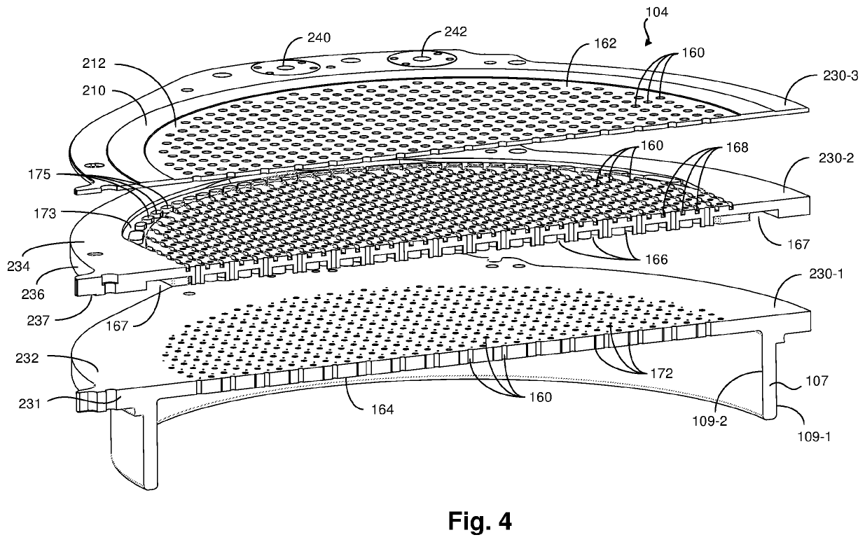

In some embodiments, the top surface 162 of the base portion 105 of the showerhead 104 includes an annular ridge 210 having a relatively small height. The annular ridge 210 is also shown in FIGS. 4, 8, and 9. The annular ridge 210 may protect the radical holes 160 during the handling of the showerhead 104 if the showerhead 104 is placed on a surface with the top surface 162 of the base portion 105 resting on the surface (i.e., if the showerhead 104 is placed face down on the surface). A width of the annular ridge 210 may be approximately (but does not necessarily have to be) the same as the thickness of the cylindrical portion 107.

The top surface 162 of the base portion 105 of the showerhead 104 may also include a recess 212 that extends from an inner diameter of the annular ridge 210 to the center of the showerhead 104. The recess 212 is also shown in FIG. 4. The diameter of the recess 212 may be approximately (but does not necessarily have to be) the same as the inner diameter of the cylindrical portion 107 of the showerhead 104. For example, the diameter of the recess 212 can be less than or equal to the inner diameter of the cylindrical portion 107 of the showerhead 104. The radical holes 160 are arranged within the area of the recess 212. The recess 212 and the annular ridge 210 together may protect the radical holes 160 during the handling of the showerhead 104.

The inner diameter of the annular ridge 210 and the diameter of the recess 212 may be approximately equal to the inner diameter of the cylindrical portion 107. In some embodiments, the inner diameter of the annular ridge 210 and the diameter of the recess 212 may be greater than the inner diameter of the cylindrical portion 107. The outer diameter of the annular ridge 210 may be greater than or equal to the outer diameter of the cylindrical portion 107. In some embodiments, the inner diameter of the annular ridge 210 and the diameter of the recess 212 may be less than the inner diameter of the cylindrical portion 107; and the outer diameter of the annular ridge 210 may be less than the outer diameter of the cylindrical portion 107. Accordingly, the width of the annular ridge 210 may be greater, equal, or less than the thickness of the cylindrical portion 107.

The base portion 105 of the showerhead 104 may include the plenum 166 and the precursor holes 172 that extend vertically from the plenum 166 through the base portion 105 and through the faceplate 164 of the showerhead 104. The plenum 166 represents a volume, space, or cavity defined in the base portion 105 in fluid communication with the precursor holes 172 but not in fluid communication with the radical holes 160.

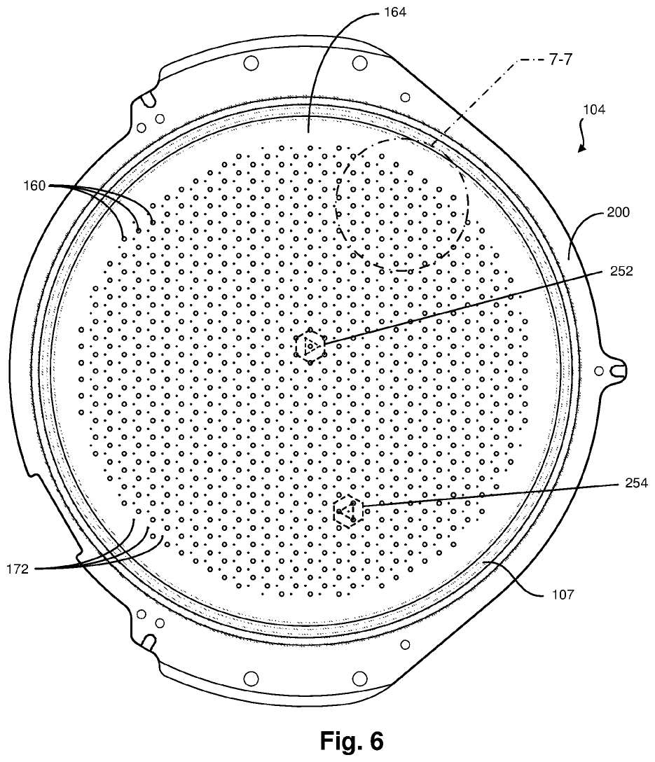

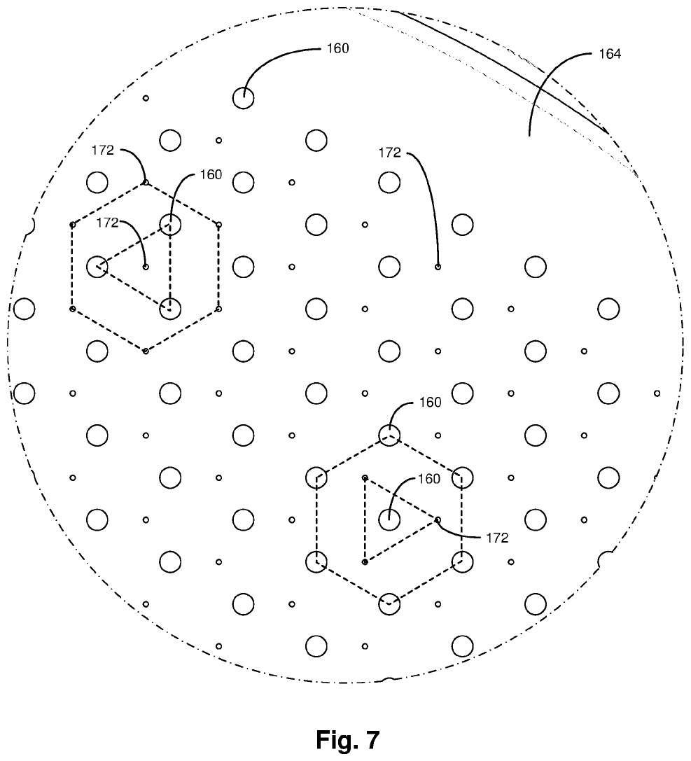

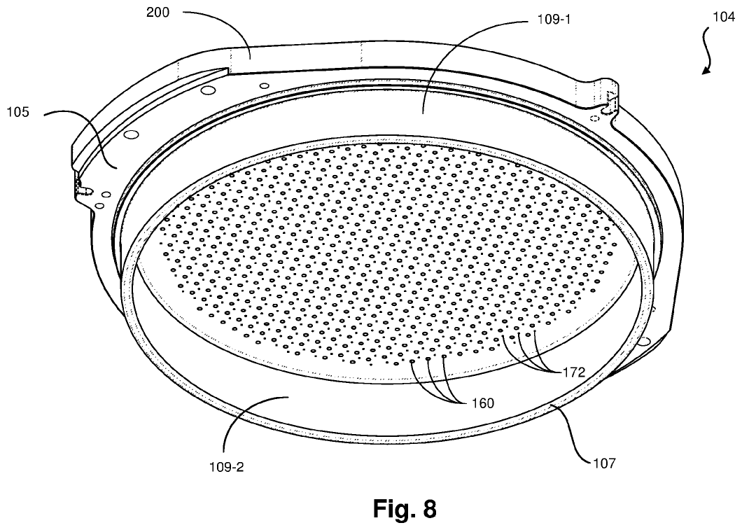

The radical holes 160 may have a greater diameter and length than the precursor holes 172. The radical holes 160 and the precursor holes 172 are cylindrical, though it will be understood that the radical holes 160 and the precursor holes 172 may be any suitable shape. The radical holes 160 and the precursor holes 172 may be arranged in a particular geometric pattern, which is described below in detail with reference to FIGS. 6 and 7. The total cross-sectional area of the radical holes 160 may be optimized to filter ions from the remote plasma 142, to pass only radicals from the remote plasma 142 through the showerhead 104 into the processing chamber 103, and to limit back-diffusion of precursors through the showerhead 104 into the plasma source 102.

In some embodiments, the radical holes 160 may be tapered/chamfered at the top end (i.e., on the side facing the plasma source 102). The radical holes 160 may alternatively or additionally be tapered/chamfered at the bottom end (i.e., on the side facing the pedestal 112). In some embodiments as shown in FIGS. 2 and 3, the radical holes 160 are not tapered/chamfered. In some embodiments, the precursor holes 172 may be tapered/chamfered at the top end (i.e., on the side facing the plasma source 102). The precursor holes 172 may alternatively or additionally be tapered/chamfered at the bottom end (i.e., on the side facing the pedestal 112).

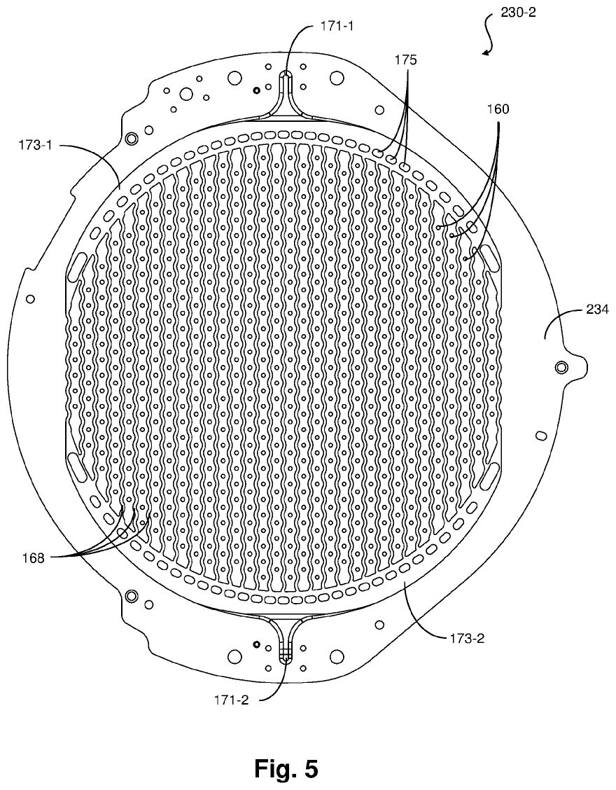

In some embodiments, the base portion 105 of the showerhead 104 includes the grooves 168 that form the cooling channel through which a coolant is circulated. The grooves 168 and the cooling channel are shown and described below in further detail with reference to FIGS. 4 and 5.

The outer wall 109-1 of the cylindrical portion 107 of the showerhead 104 does not directly contact the top plate of the processing chamber 103. Due to this feature and since the cylindrical portion 107 of the showerhead 104 extends vertically below the top surface 116 of the pedestal 112 on which the substrate 114 is arranged (see FIG. 1), the cylindrical portion 107 of the showerhead 104 provides a symmetric thermal boundary condition (i.e., a region of relatively constant temperature) around the edge of the top surface 116 of the pedestal 112 (see FIG. 1). Accordingly, the pedestal 112 can be moved vertically within (i.e., through the height of) the cylindrical portion 107 to adjust the gap between the showerhead 104 and the pedestal 112 without a significant change in the thermal boundary condition surrounding the edge of the top surface 116 of the pedestal 112, which may be advantageous during substrate processing.

Further, the cylindrical portion 107 of the showerhead 104 can also provide a relatively constant constriction to gas flow around the edge of the top surface 116 of the pedestal 112 when the pedestal 112 is moved up or down within the cylindrical portion 107. This simplifies the process of controlling the micro-volume of gases in the gap between the showerhead 104 and the pedestal 112 since the gas flow conditions around the edge of the top surface 116 of the pedestal 112 remain relatively constant because the cylindrical portion 107 surrounds and is in close proximity to the edge of the top surface 116 of the pedestal 112. Accordingly, the pedestal 112 can be moved vertically within (i.e., through the height of) the cylindrical portion 107 to adjust the gap between the showerhead 104 and the pedestal 112 without a significant change in gas flow conditions around the edge of the top surface 116 of the pedestal 112.

A tunable gap between the faceplate 164 of the showerhead 104 and the top surface 116 of the pedestal 112 allows precise control of the micro-volume in deposition (e.g., ALD) processes. Moreover, a narrow gap between the faceplate 164 of the showerhead 104 and the top surface 116 of the pedestal 112 prevents depletion of radicals in the micro-volume in the gap. Both these features can be provided due at least in part to the structure of the cylindrical portion 107 of the showerhead 104.

FIG. 4 shows a perspective cross-sectional view of the showerhead of FIG. 2 according to some implementations. The perspective cross-sectional view of the showerhead 104 shows the structure of the showerhead 104 in further detail. The showerhead 104 may comprise three components: a first component 230-1, a second component 230-2, and a third component 230-3. The first, second, and third components 230-1, 230-2, and 230-3 may be diffusion bonded together (or joined together using fasteners or brazing) to form the showerhead 104.

The first component 230-1 may include a top portion 231 and the cylindrical portion 107 of the showerhead 104. The top portion 231 of the first component 230-1, second component 230-2, and the third component 230-3 form the base portion 105 of the showerhead 104. The top portion 231 of the first component 230-1 is planar and is disc-shaped. The cylindrical portion 107 extends perpendicularly downward from a periphery of the top portion 231. The top portion 231 of the first component 230-1 extends radially outwardly beyond the outer diameter of the cylindrical portion 107. Accordingly, the diameter of the top portion 231 of the first component 230-1 is greater than the outer diameter of the cylindrical portion 107. A region of the top portion 231 within the inner wall 109-2 of the cylindrical portion 107 (i.e., within the inner diameter of the cylindrical portion 107) forms the faceplate 164 of the showerhead 104.

The radical holes 160 and the precursor holes 172 lie within a region of the faceplate 164 having a diameter that is less than or equal to the inner diameter of the cylindrical portion 107. The diameter of the region in which the radical holes 160 and the precursor holes 172 lie is greater than the diameter of the substrate 114 being processed and also greater than or equal to the outer diameter of the top surface 116 the pedestal 112 as seen in FIG. 1. The region of the faceplate 164 in which the radical holes 160 and the precursor holes 172 lie has the same diameter and area as that of the recess 212, which is shown and described above with reference to FIG. 2.

In some embodiments, the first component 230-1 may be monolithic. That is, the top portion 231 of the first component 230-1 and the cylindrical portion 107 may not be separate components that are attached to each other: rather, the first component 230)-1 may be a unitary structure, and the top portion 231 of the first component 230)-1 may be integrated with the cylindrical portion 107 as a single monolithic structure. Alternatively, in some embodiments, the top portion 231 and the cylindrical portion 107 may be separate components that are joined together (e.g., by fasteners or diffusion bonding) to form the first component 230-1.

The second component 230-2 is described with additional references made to FIGS. 4 and 5. The second component 230-2 is arranged on and is attached to a top surface 232 of the first component 230-1. The second component 230-2 is disc-shaped and has the same diameter as the top portion 231 of the first component 230-1. Accordingly, the diameter of the second component 230)-2 is also greater than the outer diameter of the cylindrical portion 107.

Top surface 234 and side surface 236 of the second component 230-2 and the top surface 232 of the first component 230-1 define the plenum 166. FIG. 4 shows the plenum 166 in further detail. As shown in FIG. 4, a bottom surface 237 of the second component 230-2 includes a semicircular or horse-shoe shaped groove 167 along a periphery of the bottom surface 237. The groove 167 is in fluid communication with the plenum 166 via a plurality of outlets. The groove 167 is in fluid communication with a gas inlet 240 provided on the third component 230-3 via one or more inlets. Accordingly, the plenum 166 is in fluid communication with the gas inlet 240 via the groove 167.

The gas inlet 240 is connected to the gas delivery system 170 shown in FIG. 1. The plenum 166 receives one or more precursors from the gas delivery system 170 via the gas inlet 240) and the groove 167. The plenum 166 is in fluid communication with the precursor holes 172 in the first component 230-1. The precursors flow from the gas inlet 240, through the groove 167, the plenum 166, and the precursor holes 172, into the processing chamber 103.

The radical holes 160 may be drilled through the first, second, and third components 230-1, 230-2, and 230-3. Therefore, each of the first, second, and third components 230-1, 230)-2, and 230-3 includes through-holes that are portions of the radical holes 160. Since the radical holes 160 pass through the second component 230-2, the second component 230-2 includes through-holes that are portions of the radical holes 160 (and are therefore also shown as 160) and that align with portions of the radical holes 160 in the first component 230-1 and the third component 230-3.

In some embodiments, the groove 167 surrounds but is not in fluid communication with the through-holes in the second component 230-2 that are portions of the radical holes 160. The through-holes in the second component 230-2 that are portions of the radical holes 160 are not in fluid communication with the groove 167, the plenum 166, and the precursor holes 172. Accordingly, the radical holes 160 are not in fluid communication with the plenum 166 and the precursor holes 172.

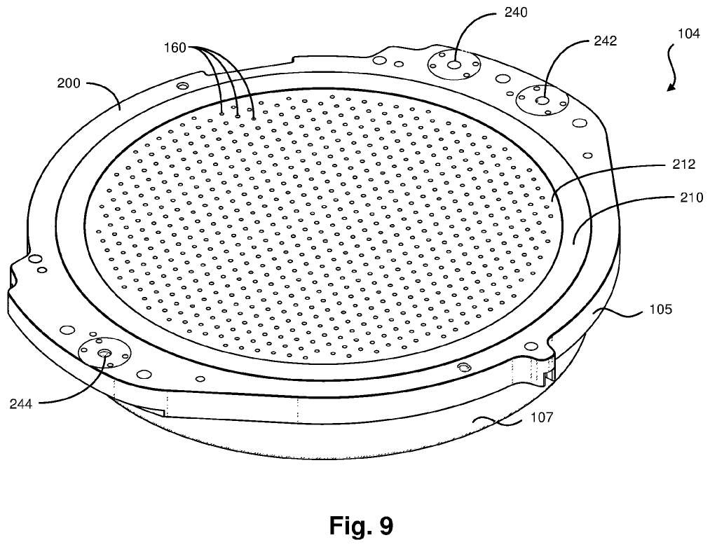

The top surface 234 of the second component 230-2 includes the grooves 168 that form the cooling channel. FIG. 5 shows a top view of a cooling channel arranged in the showerhead of FIG. 2 for circulating coolant in the showerhead according to some implementations. As shown in FIGS. 4 and 5, the top surface 234 of the second component 230-2 includes two arc-shaped or semi-circular grooves 173 (individually labeled grooves 173-1 and 173-2) along a periphery of the top surface 234. The grooves 173 are located on opposite sides of the top surface 234. The groove 173-1 includes an inlet 171-1 that is in fluid communication with a fluid inlet 242 provided on the third component 230-3, and the groove 173-2 includes an outlet 171-2 that is in fluid communication with a fluid outlet 244 (shown in FIGS. 8 and 9) provided on the third component 230-3.

The grooves 168 may be parallel to each other and extend across the top surface 234 between the grooves 173. Each of the grooves 168 has one end connected to one of the grooves 173 (e.g., groove 173-1) and the other end connected to the other one of the grooves 173 (e.g., groove 173-2). Accordingly, the grooves 168 are in fluid communication with the grooves 173. The grooves 173 and 168 may form the cooling channel of the showerhead 104.

Since the grooves 173 are semi-circular, the grooves 168 may be of varying lengths. The grooves 168 may have the same width and depth. In some embodiments, the grooves 168 may be wavy or crooked (i.e., have a zig-zagged shape), but may also be straight instead. In some embodiments, the grooves 173 are not directly connected to each other: rather, the grooves 173 are connected to each other by the grooves 168. The cooling channel formed by the grooves 173 and 168 may extend beyond the diameter of the substrate 114.

The fluid inlet 242 provided on the third component 230-3 may be connected to the fluid delivery system 180. The fluid delivery system 180 may supply the coolant to the fluid inlet 242. The coolant may flow through the fluid inlet 242, through the groove 173-1, the grooves 168, and the groove 173-2, and exit through the fluid outlet 244.

The grooves 173 include a plurality of ridges 175. The ridges 175 may be approximately oval in shape, although the ridges 175 can be of any other shape. The ridges 175 may extend vertically upwards from bottom portions of the grooves 173 and contact a bottom surface 238 of the third component 230-3. The number of the ridges 175 in each of the grooves 173 is (but does not need to be) approximately equal to the number of the grooves 168.

The ridges 175 help direct the flow of the coolant through the grooves 173 and 168. The depth of the grooves 168 may approximately equal to the height of the ridges 175. The grooves 173 and 168 may have the same depth. The groove 167 in the bottom surface 237 of the second component 230-2 may surround the grooves 173 in the top surface 234 of the second component 230-2.

In some embodiments, the grooves 173 surround but are not in fluid communication with the through-holes in the second component 230-2 that are portions of the radical holes 160. This may be seen in FIG. 5. The through-holes in the second component 230-2 that are portions of the radical holes 160 lie on either side of the grooves 168.

The third component 230-3 is arranged on and is attached to the top surface 234 of the second component 230-2. The third component 230-3 is also disc-shaped and also has the same diameter as the top portion 231 of the first component 230-1. Accordingly, the diameter of the third component 230-3 is also greater than the outer diameter of the cylindrical portion 107. Furthermore, the second and third components 230-2 and 230-3 have the same diameter.

The top surface 162 of the third component 230-3 includes the annular ridge 210 and the recess 212. The recess 212 extends from the inner diameter of the annular ridge 210 to the center of the top surface 162 of the third component 230-3.

The third component 230-3 includes the gas inlet 240, the fluid inlet 242, and the fluid outlet 244 (shown in FIGS. 8 and 9). The gas inlet 240 may be in fluid communication with the groove 167 and the plenum 166 in the second component 230-2. The fluid inlet 242 may be in fluid communication with the one of the grooves 173 (e.g., the groove 173-1) in the second component 230-2. The fluid outlet 244 may be in fluid communication with the other one of the grooves 173 (e.g., the groove 173-2) in the second component 230-2.

Accordingly, the fluid inlet 242 and the fluid outlet 244 may be in fluid communication with the grooves 173 and 168 in the second component 230-2. The coolant supplied by the fluid delivery system 180 flows into the fluid inlet 242, through the cooling channel formed by the grooves 173 and 168, and out of the cooling channel through the fluid outlet 244. In some embodiments, the coolant that exits the fluid outlet 244 may be returned to the fluid delivery system 180.

The radical holes 160 may drilled through the first, second, and third components 230-1, 230-2, and 230-3; and therefore, each of the first, second, and third components 230-1, 230-2, and 230-3 includes through-holes that are portions of the radical holes 160. Since the radical holes 160 pass through the third component 230-3, the third component 230-3 includes through-holes that are portions of the radical holes 160 (and are therefore also shown as 160) and that align with portions of the radical holes 160 in the second component 230-2 and the first component 230-1. The through-holes in the third component 230-3 that are portions of the radical holes 160 are not in fluid communication with the plenum 166 and the grooves 167, 168, and 173 in the second component 230-2. Therefore, the through-holes in the third component 230-3 that are portions of the radical holes 160 are not in fluid communication with the precursor holes 172. In some embodiments, the radical holes 160 have a uniform diameter through the first, second, and third components 230-1, 230-2, and 230-3. In some embodiments, the radical holes 160 may be tapered/chamfered at one or both of the top surface 162 and bottom surface 164 of the showerhead 104.

The first, second, and third components 230-1, 230-2, and 230-3 may be joined together by diffusion bonding. Diffusion bonding eliminates fillers typically used when brazing is used to join the components. Eliminating fillers eliminates the possibility of contamination due to residual fillers that tend to persist after brazing and subsequent cleaning. Alternatively, fasteners and/or brazing may be used to join the first, second, and third components 230-1, 230-2, and 230-3.

After the first, second, and third components 230-1, 230-2, and 230-3 are joined together (using any method), the radical holes 160 are drilled through the first, second, and the third components 230-1, 230-2, and 230-3 in a particular pattern. The precursor holes 172 are drilled through the first component 230-1 in another particular pattern. The precursor holes 172 in the first component 230-1 are aligned with the plenum 166 in the second component 230-2.

The radical holes 160 may be cylindrical and may have a greater diameter and length than the precursor holes 172. In some embodiments, the radical holes 160 may be tapered (conical) at the top end (i.e., the end facing the plasma source 102). In some embodiments, the radical holes 160 may be tapered (conical) at the bottom end (i.e., the end facing the pedestal 112). The radical holes 160 are not in fluid communication with the grooves 167, 168, and 173, the plenum 166, and the precursor holes 172.

FIGS. 6 and 7 show the radical holes 160 and the precursor holes 172. FIG. 6 shows a bottom view of the showerhead 104. FIG. 7 shows an expanded view of a portion of the bottom view of the showerhead 104. The radical holes 160 and the precursor holes 172 are arranged in a hexagonal/triangular pattern. This pattern is uniform about the center of the showerhead 104. While the hexagons and triangles are shown and described below as equilateral hexagons and triangles, other polygons and triangles may be used.

Specifically, the precursor holes 172 may be arranged at vertices of equilateral hexagons. The radical holes 160 may also be arranged at vertices of equilateral hexagons. Further, the precursor holes 172 may be arranged at vertices of equilateral triangles. In some embodiments, a radical hole 160 lies within the triangle formed by the precursor holes 172 at equal distances from the vertices of the triangle. The radical holes 160 may also be arranged at vertices of equilateral triangles. In at least some triangles formed by the radical holes 160, a precursor hole 172 lies in the triangle formed by the radical holes 160. In some embodiments, the precursor hole 172 lies at equal distances from the vertices of the triangle formed by the radical holes 160.

As shown at 252 in FIG. 6, the radical holes 160 are arranged at vertices of equilateral hexagons, and within a hexagon formed by the radical holes 160; the precursor holes 172 are arranged at vertices of a triangle, with a radical hole 160 arranged within the triangle. As shown at 254 in FIG. 6, the precursor holes 172 are arranged at vertices of equilateral hexagons, and within a hexagon formed by the precursor holes 172: the radical holes 160 are arranged at vertices of a triangle, with a precursor hole 172 arranged within the triangle.

The radical holes 160 and the precursor holes 172 are arranged in the above pattern relatively densely throughout the faceplate 164. For example, an average density of the radical holes 160 and the precursor holes 172 may be about 4.5 holes per square inch. In some embodiments, the average density of the radical holes 160 and the precursor holes 172 may range between 3 to 6 holes per square inch or between 4 to 5 holes per square inch.

Additionally, the number of radical holes 160 and the number of precursor holes 172 may be nearly equal. In some embodiments, the number of radical holes 160 may be slightly greater than the number of precursor holes 172. For example, a ratio of the number of radical holes 160 to the number of precursor holes 172 may be between 1.00 and 1.10 or between 1.00 and 1.05.

In addition, the radical holes 160 and the precursor holes 172 may be distributed in the aforementioned pattern and at the aforementioned density throughout the faceplate 164 (i.e., from the center to the inner diameter of the cylindrical portion 107). The pattern and the density of the radical holes 160 and the precursor holes 172 extend in the faceplate 164 radially beyond the diameter of the substrate 114 up to the inner diameter of the cylindrical portion 107. The radial extension of the pattern and the density of the radical holes 160 and the precursor holes 172 beyond the diameter of the substrate 114 ensures that the pattern and the density are uniform from the center of the faceplate 164 at least up to where the outer diameter of the substrate 114 extends on the faceplate 164.

Due to the extent and uniformity of these pattern and density features, materials can be uniformly deposited (or uniformly etched) on the substrate 114. For example, a non-uniformity of 0.0%, less than 0).1%, less than 0.5%, or less than 1% can be achieved in material deposited on the substrate 114 using the plasma source 102 and the showerhead 104.

In addition, characteristics such as size (diameter and length) and the number of the radical holes 160 determine the efficiency with which the radicals from the remote plasma 142 can pass from the plasma source 102 through the showerhead 104 into the processing chamber 103. While some of these characteristics can be increased to increase the number of radicals that can pass through the radical holes 160, at some size or aspect ratio of the radical holes 160, the showerhead 104 may not be able to effectively filter the ions from the remote plasma 142.

In some embodiments, the radical holes 160 may have a first diameter (D₁) and a first length (L₁) optimized to filter ions and pass radicals from the remote plasma 142. The precursor holes 172 may have a second diameter (D₂) and a second length (L₂). The first diameter (D₁) is greater than the second diameter (D₂), and the first length (L₁) is greater than ( ) the second length (L₂). In some embodiments, the first diameter (D₁) is at least two times greater than the second diameter (D₂).

Typically, a ratio of the length to diameter of the radical holes 160 is between about 5.0 and about 8.0, or between about 6.5 and about 7.0, or about 6.8 in order to optimize ion filtering and radical delivery to the substrate 114. For example, the first length (L₁) can be about 0.850 inches and the first diameter (D₁) can be about 0.125 inches to obtain an L₁/D₁ ratio of 6.8. Such hole sizing is believed to facilitate ion filtering and promote radical delivery from the showerhead 104 to the substrate 114.

To optimize radical delivery to the substrate 114, it is believed that the radical holes 160 may be designed such that a percentage of area that is open for the radicals to pass from the plasma source 102 through the showerhead may be relatively high. The percentage of area that is open for radicals to pass from the plasma source 102 through the showerhead 104 may be defined as a radicals open percentage (also referred to as “R open %”). This radicals open percentage may be defined as a ratio of the total cross-sectional area of all the radical holes 160 to a cross-sectional area of the bottom of the plasma source 102 that is attached to the showerhead 104. The plasma source 102 and the showerhead 104 are designed such that the cross-sectional area of the bore 106 (i.e., the cross-sectional area of the inner wall 109-2 of the cylindrical portion 107) of the showerhead 104 is substantially the same as, and therefore can be substituted for, the cross-sectional area of the bottom of the plasma source 102. Therefore, the percentage of area that is open for the radicals to pass from the plasma source 102 through the showerhead 104 can be defined as a ratio of a sum of a cross-sectional area of the radical holes 160 to a cross-sectional area defined by an inner diameter of the cylindrical portion 107 of the showerhead 104. Mathematically, this ratio is equal to the number of radical holes 160 multiplied by a square of the diameter of the radical holes 160 divided by a square of the inner diameter of the bore 106. This can be represented by the following formula: R open %=[(number of radical holes)×(πD₁²/4)]/(πD_{b}²/4), where D_{b} refers to the diameter of the bore 106 and D₁ refers to the diameter of the radical hole 160.

Ordinarily, the ratio of the sum of the cross-sectional area of the radical holes 160 to the cross-sectional area defined by the diameter of the bore 106 is between about 2.5% and about 8.0%, between about 3.0% and about 7.0%, between about 4.0% and about 6.0%, between about 4.5% and about 5.5%, or about 5.14%. For example, the first diameter (D₁) of the radical holes 160 can be about 0). 125 inches, the diameter (D_{b}) of the bore 106 can be about 14.55 inches, and the number of radical holes 160 can be about 696 to obtain an R open % of 5.14%. Such a percentage of area open for radicals to pass is believed to optimize radical delivery to the substrate 114.

However, having a percentage of area open for radicals to pass being between about 4.0% and about 6.0% may be undesirable in some implementations. Such a percentage of area open for radicals to pass may be too high and lead to back-diffusion of precursors from the processing chamber 103 to the plasma source 102 through the showerhead 104. Without being limited by any theory, increased delivery of precursors through the precursor holes 172 to the substrate 114 may result in back-streaming of the precursors through the radical holes 160. When precursors are introduced into the plasma source 102, they may be difficult to purge out. During subsequent plasma generation and substrate processing, the precursors may mix with the remote plasma 142 and generate contaminant particles. This may lead to contaminant particles on the substrate 114 that increases parasitic defect formation and otherwise reduces performance.

To limit the effects of back-streaming while optimizing ion filtering and radical delivery to the substrate 114, the showerhead of the present disclosure may employ a reduced percentage of area open for radicals to pass. Specifically, the reduced percentage of area open for radicals to pass may be equal to or less than about 3.0%, equal to or less than about 2.5%, equal to or less than about 2.0%, between about 0.5% and about 3.0%, or between about 0.5% and about 2.0%. Therefore, the ratio of the sum of the cross-sectional area of the radical holes 160 to the cross-sectional area defined by the inner diameter of the cylindrical portion 107 may be equal to or less than about 3.0%, equal to or less than about 2.5%, equal to or less than about 2.0%, between about 0).5% and about 3.0%, or between about 0.5% and about 2.0%. For instance, the ratio of the sum of the cross-sectional area of the radical holes 160 to the cross-sectional area defined by the inner diameter of the cylindrical portion 107 may be 1.85%. Where the ratio is between about 0.5% and about 3.0%, the diameter of the radical holes 160 may be between about 1.0 mm and about 2.4 mm.

In some embodiments, the reduced percentage of area open for radicals can be achieved by a reduced diameter of the radical holes 160. The reduced diameter increases the L₁/D₁ ratio and decrease the R open %. By way of an example, the first diameter of the radical holes 160 can be between about 0.01 inches and about 0.1 inches, between about 0.03 inches and about 0.1 inches, or between about 0).05 inches and about 0.1 inches. In some embodiments, the ratio of the first length to the first diameter, or the L₁/D₁ ratio, can be between about 8 and about 15 or between about 10 and about 12.

The percentage of the area open for radicals can be configured to limit the back-streaming of precursors and other unwanted species through the showerhead 104 into the plasma source 102. The percentage of the area can also affect the efficiency with which the radicals can pass while filtering the ions from the remote plasma 142. However, reducing this percentage of the area may not have a substantially detrimental effect on the efficiency of radical delivery to the substrate 114. Using the pattern and hole density of the radical holes 160 and precursor holes 172 described above, the percentage of the area open for radicals (e.g., between about 0.5% and about 3.0%) can limit back-diffusion of precursors, promote ion filtering, and promote radical delivery. The percentage of the area open for radicals can also improve non-uniformity when performing deposition operations such as ALD processes or CVD processes. For example, to achieve near-zero non-uniformity (see examples above) in the material deposited on the substrate 114, in addition to the pattern and the density of the radical holes 160 and the precursor holes 172 described above, the percentage of the area that is open for the radicals to pass through the showerhead 104 may be about 1.85%. For example, the percentage of the area may be between 0.5% and 3.0%. Or, the percentage of the area may be between 0.5% and 2.0%.

Further, since optimizing the percentage of the area limits back-diffusion of precursors while maintaining a desirable efficiency with which the radicals can pass through the showerhead into the processing chamber 103, process cycles (e.g., ALD cycles) can be performed rapidly using the pattern, the density, and the percentage of the area designed as above. Since the process cycles can be performed rapidly, the rate at which substrates can be processed in a given amount of time (i.e., throughput) is increased.

FIG. 8 shows an off-angle bottom view of the showerhead 104. In this view; the radical holes 160 and the precursor holes 172 are visible. The radical holes 160 and the precursor holes 172 are shown as extending all the way to the inner diameter of the cylindrical portion 107 of the showerhead 104. In addition, the extent (or height) of the cylindrical portion 107 of the showerhead 104 relative to the base portion 105 of the showerhead 104 can be perceived from the bottom of the showerhead 104 in this view.

FIG. 9 shows an isometric top view of the showerhead 104. In this view, only the radical holes 160 are visible, and the precursor holes 172 are not visible. Moreover, the gas inlet 240) that connects to the plenum 166 is shown. Also, the fluid inlet 242 as well as the fluid outlet 244 that connect to the channel formed by the grooves 168 are shown. The annular ridge 210 and the recess 212 are shown in this view.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

Spatial and functional relationships between elements (for example, between modules, circuit elements, semiconductor layers, etc.) are described using various terms, including “connected,” “engaged,” “coupled.” “adjacent.” “next to.” “on top of,” “above,” “below,” and “disposed.” Unless explicitly described as being “direct.” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements.

In some implementations, a controller is part of a system, which may be part of the above-described examples. Such systems can comprise semiconductor processing equipment, including a processing tool or tools, chamber or chambers, a platform or platforms for processing, and/or specific processing components (a pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A showerhead for use in a semiconductor processing apparatus, the showerhead comprising:
a base portion having a plenum within the showerhead; and
a cylindrical portion extending perpendicularly from the base portion, the base portion having a greater diameter than an outer diameter of the cylindrical portion, wherein the base portion comprises a first set of holes each having a first diameter and a first length and a second set of holes each having a second diameter and a second length, wherein the first set of holes and the second set of holes are distributed from a center of the base portion to an inner diameter of the cylindrical portion, wherein the first set of holes extend from a top surface of the base portion to a bottom surface of the base portion, wherein the second set of holes extend from the plenum to the bottom surface of the base portion, wherein the first diameter is greater than the second diameter and the first length is greater than the second length, wherein a ratio of a sum of a cross-sectional area of the first set of holes to a cross-sectional area of the cylindrical portion is between about 0.5% and about 3.0%.

2. The showerhead of claim 1, wherein the first and second sets of holes are arranged in a hexagonal pattern, a triangular pattern, or a combination of a hexagonal pattern and a triangular pattern.

3. The showerhead of claim 1, wherein a density of the first and second sets of holes is between about 3 holes per square inch and about 6 holes per square inch.

4. The showerhead of claim 1, wherein a ratio of the first length (L₁) to the first diameter (D₁) is between about 8 and about 15.

5. The showerhead of claim 4, wherein the ratio of the first length (L₁) to the first diameter (D₁) is between about 10 and 12.

6. The showerhead of claim 1, wherein the first diameter is between about 0.03 inches and about 0.1 inches.

7. The showerhead of claim 1, further comprising:
a first component having the base portion and the cylindrical portion:
a second component being disc-shaped and comprising first through-holes aligned with the first set of holes in the base portion, wherein the second component has a top surface, side surfaces, and a bottom surface attached to the base portion of the first component on a side opposite to the cylindrical portion and defining the plenum that is in fluid communication with the second set of holes and separate from the first set of holes; and
a third component being disc-shaped and comprising second through-holes aligned with the first through-holes in the second component and with the first set of holes in the first component, and having a bottom surface attached to the top surface of the second component.

8. The showerhead of claim 7, wherein the top surface of the second component comprises a pair of arc-shaped grooves along a periphery and on opposite ends of the top surface and wherein the top surface of the second component further comprises a plurality of grooves extending between the pair of arc-shaped grooves.

9. The showerhead of claim 8, wherein the third component comprises a gas inlet in fluid communication with the plenum, a fluid inlet in fluid communication with the first one of the pair of arc-shaped grooves, and a fluid outlet in fluid communication with the second one of the pair of arc-shaped grooves.

10. The showerhead of claim 1, wherein the showerhead is configured to limit back-diffusion of gases supplied from the second set of holes through the first set of holes.

11. The showerhead of claim 1, wherein the inner diameter of the cylindrical portion is greater than a diameter of a substrate being processed.

12. The showerhead of claim 1, wherein the first set of holes are arranged in a hexagonal pattern, wherein the second set of holes lie on vertices of triangles within hexagons defined by the first set of holes, and wherein one of the first set of holes lies within each of the triangles.

13. The showerhead of claim 1, wherein the second set of holes are arranged in a hexagonal pattern, wherein the first set of holes lie on vertices of triangles within hexagons defined by the second set of holes, and wherein one of the second set of holes lies within each of the triangles.

14. The showerhead of claim 1, wherein a ratio of a number of the first set of holes to a number of the second set of holes is between about 1.00 and about 1.05.

15. A showerhead for use in a semiconductor processing apparatus, the showerhead comprising:
a first component comprising a disc-shaped portion and a cylindrical portion extending perpendicularly from the disc-shaped portion, the disc-shaped portion having a greater diameter than an outer diameter of the cylindrical portion, the disc-shaped portion comprising a first set of holes and a second set of holes, the first set of holes each having a first length and a first diameter and the second set of holes each having a second length and a second diameter, wherein the first diameter is greater than the second diameter and the first length is greater than the second length, wherein the first and second sets of holes are distributed from a center of the disc-shaped portion to an inner diameter of the cylindrical portion, wherein a ratio of a sum of a cross-sectional area of the first set of holes to a cross-sectional area of the cylindrical portion is between about 0.5% and about 3.0%:
a second component being disc-shaped and comprising first through-holes aligned with the first set of holes in the first component, wherein the second component has a top surface, side surfaces, and a bottom surface attached to the disc-shaped portion of the first component on a side opposite to the cylindrical portion and defining a plenum that is in fluid communication with the second set of holes in the first component and that is separate from the first set of holes in the first component; and
a third component being disc-shaped and comprising second through-holes aligned with the first set of holes in the second component and with the first set of holes in the first component, wherein the third component has a bottom surface attached to the top surface of the second component.

16. The showerhead of claim 15, wherein the top surface of the second component comprises a pair of arc-shaped grooves along a periphery and on opposite ends of the top surface of the second component, and wherein the top surface of the second component further comprises a plurality of grooves extending between the pair of arc-shaped grooves.

17. The showerhead of claim 15, wherein the third component further comprises an annular ridge on a top surface of the third component along a periphery of the third component, wherein the third component further comprises a recess extending from an inner diameter of the annular ridge to a center of the top surface of the third component.

18. The showerhead of claim 15, wherein the first and second sets of holes are arranged in a hexagonal pattern, a triangular pattern, or a combination of a hexagonal pattern and a triangular pattern.

19. The showerhead of claim 15, wherein a density of the first and second sets of holes is between about 3 holes per square inch and about 6 holes per square inch.

20. The showerhead of claim 15, wherein a ratio of the first length (L₁) to the first diameter (D₁) is between about 8 and about 15.

21. A plasma apparatus comprising:
a processing chamber;
a pedestal in the processing chamber and configured to support a substrate;
a plasma source disposed above the processing chamber; and
a showerhead disposed between the processing chamber and the plasma source, wherein the showerhead comprises:
a base portion having a plenum within the showerhead; and
a cylindrical portion extending perpendicularly from the base portion, the base portion having a greater diameter than an outer diameter of the cylindrical portion, wherein the base portion comprises a first set of holes each having a first diameter and a first length and a second set of holes each having a second diameter and a second length, wherein the first set of holes and the second set of holes are distributed from a center of the base portion to an inner diameter of the cylindrical portion, wherein the first set of holes extend from a top surface of the base portion to a bottom surface of the base portion, wherein the second set of holes extend from the plenum to the bottom surface of the base portion, wherein the first diameter is greater than the second diameter and the first length is greater than the second length, wherein a ratio of a sum of a cross-sectional area of the first set of holes to a cross-sectional area of the cylindrical portion is between about 0.5% and about 3.0%.

22. The plasma apparatus of claim 21, wherein the plasma source is configured to generate plasma and supply the plasma to the showerhead, wherein the first set of holes in the showerhead is configured to filter ions from the plasma and pass radicals from the plasma through the showerhead into the processing chamber.

23. The plasma apparatus of claim 21, wherein the first and second sets of holes are arranged in a hexagonal pattern, a triangular pattern, or a combination of a hexagonal pattern and a triangular pattern.

24. The plasma apparatus of claim 21, wherein a density of the first and second sets of holes is between about 3 holes per square inch and about 6 holes per square inch.

25. The plasma apparatus of claim 21, wherein a ratio of the first length (L₁) to the first diameter (D₁) is between about 8 and about 15.
